(19) United States
(12) Patent Application Publication
(10) Pub. No.: US 2026/0058497 A1
(43) Pub. Date: Feb. 26, 2026

(54) MULTIPLE-OUTPUT TUNABLE IMPEDANCE MATCHING NETWORKS

(71) Applicant: Massachusetts Institute of Technology, Cambridge, MA (US)

(72) Inventor: David J. PERREAULT, Cambridge, MA (US)

(73) Assignee: Massachusetts Institute of Technology, Cambridge, MA (US)

(21) Appl. No.: 19/103,100

(22) PCT Filed: Aug. 11, 2023
(86) PCT No.: PCT/US2023/072058

§ 371 Date: Feb. 11, 2025

Related U.S. Application Data
(60) Provisional application No. 63/397,424, filed on Aug. 12, 2022.

(51) Int. Cl. H02J 50/20; H03F 1/56; H03H 7/38

(52) U.S. Cl. CPC H02J 50/20; H03F 1/565; H03H 7/38; H03F 2200/451

(57) ABSTRACT

Described is a multi-output tunable matching networks (MOTMN) that can transfer energy from a single input to multiple outputs with varying load impedances coupled thereto while controlling one or more of: (1) an impedance (Z_{IN}) seen at the input of the MOTMN; (2) a distribution of rf power to the multiple outputs of the MOTMN; and (3) phases (including relative phases) of rf signals propagating through the MOTMN.

### BACKGROUND

Impedance matching networks are circuit building blocks for improving power transfer and efficiency within many radio-frequency (rf) systems. In rf transmitters, for instance, matching an output impedance of an rf power amplifier (PA) to a driving-point impedance of a transmit antenna increases (and ideally, maximizes) an amount of power emitted through the antenna, reduces (and ideally, minimizes) post-PA power loses (e.g., power loses which occur due to undesirable impedance mismatch between the output of the PA and an input of the antenna). Matching an output impedance of an rf amplifier to a driving-point impedance of a transmit antenna via an impedance matching network may also alleviate the need for expensive, bulky and lossy circuit components such as isolators included in a circuit or system to protect against power reflected from the antenna input back toward the output of the rf amplifier (e.g., the rf PA) due to impedance mismatch between the rf amplifier output port and the input port of the transmit antenna.

Conventional matching networks which can transform a single load impedance to a single input impedance are known. Also known are resistance compression networks which can be used to transform an (ideally) matched set of loads to a single narrow-range input impedance, while delivering equal power to the matched loads. Thus, theory and techniques for designing highly efficient “fixed” impedance matching networks (i.e., impedance matching networks which match a known (or “fixed”) impedance at an output port of a PA to a known (or “fixed”) impedance at an input port of an antenna) are known.

Electronically-controlled, tunable impedance matching networks (TMNs) (also sometimes known as automatic antenna tuning units) offer substantial benefits when it comes to the implementability of reconfigurable and adaptive rf systems. TMNs are highly versatile and can be employed for controlling driving-point impedance of loads, and/or they can be incorporated as part of PAs in transmitters to achieve frequency agility and improve overall system efficiency.

### SUMMARY

In accordance with the concepts, systems, device and techniques described herein it has been recognized that depending upon how the variable reactances are realized, a TMN might be classified as continuously-variable (“analog”), discretely-variable (“digital”) or hybrid (e.g., having some elements continuously-variable and other elements discretely variable).

In accordance with the concepts, systems, device and techniques described herein it has been recognized that variable reactances for tunable matching networks (and hence the TMNs themselves) may also be characterized by the speed at which the tunable reactances can be varied (and hence the speed with which a TMN can adjust impedance matching). Mechanically-driven variable capacitors and varactors only provide relatively slow variation of reactance, limited by the speed with which the capacitor can be mechanically adjusted or the bias voltage can be changed, respectively. On the other hand, dynamic frequency tuning, phase-switched impedance modulation, and discrete switching of tunable reactive component arrays allow for very rapid variations in reactance (up to rf-cycle by rf-cycle adjustment).

Most matching networks transform a single load impedance to a single input impedance. Networks such as resistance compression networks are sometimes used to transform an (ideally) matched set of loads to a single narrow-range input impedance, while delivering equal power to the matched loads.

However, in accordance with the concepts, systems, device and techniques described herein, a different goal—considered here—is the design of tunable matching networks that can transfer energy (ideally losslessly) from a single input to multiple outputs, and able to control (1) the impedance Z_{IN} seen at the input of the network, and (2) the distribution of rf power to the multiple outputs. The outputs may have loads having independently varying load impedances coupled thereto. Or the loads may have some degree of coupling (e.g., mutual impedance) among them. In some implementations it is further desirable to be able to control (e.g., match) the relative phases of the rf voltages or currents at the multiple outputs (possibly also with respect to the input voltage), and to achieve extremely fast and precise tunability.

Numerous applications can benefit from such a multiple-output tunable matching network. For example, some plasma systems have both a main and an rf bias coil. A multiple-output TMN having the described properties could enable both coils to be driven from a single rf amplifier, with power control to the two coils controlled by the TMN. Likewise, one may have a plasma system with multiple coils to enable control of plasma uniformity across a wide area. Wireless power transfer systems and induction heating systems may also have multiple coils, enabling control of power transfer to different loads and/or different spatial locations. Likewise, rf communication systems often have different antennas for delivering power to different sectors. In each of these cases, a fast, wide-range multiple-output TMN would allow power control to the different outputs to be achieved with a single rf amplifier or inverter. A multi-output dc-dc converter could likewise be implemented with a single rf inverter, a multi-output TMN providing multiple ac outputs, and multiple rectifiers to rectify those outputs, with the multi-output TMN used to control the flow of power to (and regulate) the different dc outputs.

In accordance with a further aspect described herein a method for matching impedances at output port of a multiple-output TMN includes measuring or otherwise determining an input impedance of the multiple-output TMN and measuring or otherwise determining impedances of respective loads coupled to respective ones of the output ports of the multiple-output TMN, calculating or otherwise determining target reactance values (or value changes) needed to adjust an input impedance to a desired level and relative power flow to a desired level, and setting or updating variable reactance values of one or more variable reactance elements to the determined target reactance values (or value changes).

In one aspect of the concepts described herein, a multi-output tunable matching network (MOTMN) has an input port and a plurality of output ports with each output port configured to have one or more loads coupled thereto and wherein at least one of the loads has an impedance which varies. The MOTMN includes a like plurality of branches with each branch having a first end coupled to the input of the MOTMN and a second end coupled to a respective ones of the plurality of MOTMN outputs; and each branch of the plurality of branches comprising one or more tunable reactive elements, wherein the tunable reactive elements are provided having reactance values selected to: (1) control the distribution of power flow from the MOTMN input to ones of the plurality of outputs of the MOTMN as load impedances vary; and (2) match an input impedance at the single input of the MOTMN to a desired value even as load impedances vary.

In embodiments, the multi-output tunable matching network may comprise N+1 tunable reactive elements where N is an integer corresponding to the number of outputs in the multi-output tunable matching network.

In embodiments, the multi-output tunable matching network may comprise 2N tunable reactive elements where N is an integer corresponding to the number of outputs in the multi-output tunable matching network.

In embodiments, at least one of the tunable reactive elements is a discretely-tuned element and at least one of the tunable reactive elements is continuously-tunable element.

In embodiments, at least one of the tunable reactive elements is a discretely-tuned elements are selected for a first subset of the elements and continuously-tunable elements are selected for the second subset of the elements while still achieving acceptable relative phase among outputs and acceptable precision of net impedance and relative power control.

In one aspect of the concepts described herein, a multi-output tunable matching network (MOTMN) includes at least one input, a plurality of outputs, each output configured to be coupled to a load network, a plurality of tunable reactive elements having variable reactance values, each of the tunable reactive elements coupled between the at least one input and at least one of the plurality of outputs. The MOTMN further includes a controller for controlling the variable reactance values of one or more of the tunable reactive elements to achieve (1) relative distribution of power flow from the at least one input to ones of the plurality of MOTMN outputs; and (2) substantially match the input impedance of the MOTMN to a desired value even as impedances presented to one or more of the plurality of outputs of the TMN by the load network vary.

In embodiments, the multi-output tunable matching network comprises 2N+1 tunable reactive elements where N is an integer corresponding to the number of outputs in the multi-output tunable matching network.

In embodiments, the multi-output tunable matching network comprises 3N tunable reactive elements where N is an integer corresponding to the number of outputs in the multi-output tunable matching network.

In a still further aspect of the concepts described herein, a tunable matching network (TMN) comprises two outputs, a pair of interconnected single-input, single-output L-section matching networks having four variable reactance elements having respective ones of variable reactance values X_{1A}, X_{1B}, X_{2A} and X_{2B}; and a controller coupled to the pair of interconnected single-input, single-output L-section matching networks, wherein in response to inputs provided to the controller, the controller provides control signals to set reactance values X_{1A}, X_{1B}, X_{2A} and X_{2B} of the variable reactance elements to obtain real-valued branch input impedances Z_{IN1}=R_{IN1}=1/Y_{IN1}=1/G_{IN1} and Z_{IN2}=R_{IN2}=1/Y_{IN1}=1/G_{IN2} that are larger than load impedances R_{L1} and R_{L2}.

In embodiments, the reactance values X_{1A}, X_{1B}, X_{2A} and X_{2B} of the variable reactance elements are set to provide a net input impedance Z_{IN}=R_{IN}=1/(Y_{IN1}+Y_{IN2})=1/(G_{IN1}+G_{IN2}).

In embodiments, wherein the reactance values X_{1A}, X_{1B}, X_{2A} and X_{2B} of the variable reactance elements are set such that a sum of the input conductances control a net input impedance of the TMN.

In accordance with a still further aspect of the concepts described herein, a tunable matching network (TMN) comprises two outputs, three tunable reactance elements having respective ones of tunable impedances jX_{A}, jX_{1B}, and jX_{2B}; and a controller for controlling the values of the three tunable reactance elements such that a desired proportion of power from the input is delivered to each output and the input impedance of the tunable matching network is controlled to a desired value.

An extended pi multi-output tunable matching network comprises a first plurality of interconnected pi matching networks having a second plurality of variable reactance elements to support a third plurality of outputs wherein the pi networks support creating input resistances above or below that of their respective load resistances and wherein a single reactance is controlled to jX_{A}=X_{1A}∥X_{2A}.

In embodiments, the extended pi multi-output tunable matching network comprises 2N+1 variable reactance elements for N outputs of the extended pi multi-output tunable matching network.

In embodiments, the extended pi multi-output tunable matching network comprises 3N variable reactance elements for N outputs of the extended pi multi-output tunable matching network.

In embodiments, the extended pi multi-output tunable matching network comprises means for dynamically adjusting a center resistance of each of the pi networks to regulate relative phases of voltages v_{L1} and v_{L2} with respect to an input voltage v_{IN}.

In embodiments, the plurality of interconnected pi matching networks is provided as two interconnected pi matching networks having six tunable variable reactance elements to support two outputs.

In embodiments, the plurality of interconnected pi matching networks is provided as two interconnected pi matching networks having five variable reactance elements to support two outputs.

In embodiments, pi networks of the extended pi multi-output tunable matching network supports creating input resistances above or below that of their respective load resistances.

A multi-output tunable matching network having N-outputs and includes a minimum of 2N+1 variable reactance elements.

In embodiments, the MOTMN includes input-side shunt elements responsive to one of PSIM or DFT tuning techniques.

In embodiments, the MOTMN includes a combination of discretely-tuned elements and continuously-tunable elements (i.e., at least one of the tunable reactive elements is a discretely-tuned element and at least one of the tunable reactive elements is continuously-tunable element).

In embodiments, at least one of the tunable reactive elements is a discretely-tuned elements are selected for a first subset of the elements and continuously-tunable elements are selected for the second subset of the elements while still achieving acceptable relative phase among outputs and acceptable precision of net impedance and relative power control.

### DESCRIPTION OF THE SEVERAL VIEWS OF THE DRAWINGS

The manner and process of making and using the disclosed embodiments may be appreciated by reference to the figures of the accompanying drawings. It should be appreciated that the components and structures illustrated in the figures are not necessarily to scale, emphasis instead being placed upon illustrating the principals of the concepts described herein. Like reference numerals designate corresponding parts throughout the different views. Furthermore, embodiments are illustrated by way of example and not limitation in the figures, in which:

FIG. 1 is a block diagram of a multiple-output tunable impedance matching network capable of controlling both an input impedance Z_{IN} and controlling a flow of power from an input of the multiple-output tunable impedance matching network to multiple outputs of the multiple-output tunable impedance matching network at which respective ones of multiple effective load impedances Z_{L1} to Z_{LN} may be coupled;

FIG. 2 is a schematic diagram of a two-output tunable impedance matching network able to control both an input impedance Z_{IN} two-output tunable impedance matching network and control the flow of power from an input of the two-output tunable impedance matching network to the two outputs of the two-output tunable impedance matching network at which respective ones of two load impedances Z_{L1} and Z_{L2} may be coupled. The network uses four tunable reactance elements having tunable impedances jX_{1A}, jX_{1B}, jX_{2A} and jX_{2B} (i.e., this network uses 2N tunable reactance elements);

FIG. 3 is a schematic diagram of a two-output tunable impedance matching network which uses a minimum three (3) tunable reactance elements having tunable impedances jX_{A}, jX_{1B}, and jX_{2B} to control both an input impedance Z_{IN} of the two-output tunable impedance matching network and control a flow of power from the input of the two-output tunable impedance matching network to the two outputs of the two-output tunable impedance matching network at which respective ones of two effective load impedances Z_{L1} and Z_{L2} may be coupled;

FIG. 4 is a schematic diagram of an N-output tunable impedance matching network which uses tunable reactance elements having tunable impedances jX_{1A}-jX_{1N} and jX_{1B}, . . . , jX_{NB} to control both the input impedance Z_{IN} and the distribution of power from the input to the effective load impedances Z_{L1} to Z_{LN};

FIG. 4A is a schematic diagram of an N-output tunable impedance matching networks able to control both the input impedance Z_{IN} and control the distribution of power from the input to the effective load impedances Z_{L1} to Z_{LN}. This network uses a minimum N+1 tunable reactance elements having tunable impedances j_{XA}, jX_{1B}, . . . , jX_{NB};

FIG. 5 is a schematic diagram of a two (2) output tunable matching network based on an extended-pi structure provided by using two interconnected pi networks having 6 tunable components;

FIG. 5A is a schematic diagram of a two (2) output tunable matching networks based on an extended-pi structure provided by using a network combining reactance elements to only require 5 tunable components

FIG. 6 is a schematic diagram of an N-output tunable matching network based on an extended-pi structure and which uses 2N+1 tunable reactance elements; and

FIG. 7 is a block diagram of a system employing a multiple output tunable matching network (MOTMN); and

FIG. 8 is a flow diagram of a method for operating a multiple-output tunable matching network (MOTMN).

### DETAILED DESCRIPTION

In general overview, described herein are multiple-output tunable matching networks (MOTMNs) that can transfer energy (ideally losslessly) from a single input to multiple outputs. In embodiments, an MOTMNs provided in accordance with the concepts described herein are capable of controlling an impedance (Z_{IN}) seen at the input of the MOTMN. In embodiments, MOTMNs provided in accordance with the concepts describe herein are capable of controlling the distribution of rf power to the multiple outputs of the MOTMN.

The MOTMN outputs may have loads with independently varying load impedances coupled thereto. Or the MOTMN outputs may have loads with some degree of coupling (e.g., mutual impedance) among them. Or the MOTMN outputs may have a combination of loads with independently varying load impedances coupled thereto including loads with some degree of coupling (e.g., mutual impedance) among them. Under all of these conditions, MOTMNs provided in accordance with the concepts describe herein are capable of controlling: (1) an impedance (Z_{IN}) seen at the input of the MOTMN; (2) a distribution of rf power to the multiple outputs of the MOTMN; and (3) phases (including relative phases) of rf signals propagating through the MOTMN.

The MOTMN includes one or more tunable elements. In embodiments, at least some of the one or more tunable elements are disposed in output signal paths (or branches) of the MOTMN. By selecting and/or changing (e.g., tuning) impedance values of at least some of the one or more tunable elements, the MOTMN controls (e.g., selects and/or changes) the relative phases of the rf voltages or currents at the multiple outputs of the MOTMN.

In embodiments, such control of the relative phases of the rf voltages or currents at the multiple outputs of the MOTMN may be with respect to an rf signal (e.g., a voltage) provided to an input of the MOTMN.

In embodiments, such control of the relative phases of the rf signals (i.e., rf voltages or currents) at the multiple outputs of the MOTMN may include matching phases and/or amplitudes of rf voltages and/or currents of rf signals.

In embodiments, such control of the relative phases of the rf voltages or currents at the multiple outputs of the MOTMN may be with respect to an rf signal provided to an input of the MOTMN and/or may include matching phases and/or amplitudes of rf signals (e.g., voltages of rf signals).

Thus, the tunable impedance elements of the MOTMN provide an additional degree of freedom to control one or more of: relative phase of rf signals propagating through the MOTMN; MOTMN input impedance; and power distribution at outputs of the MOTMN.

The selected values of the one or more tunable impedance elements enable control of relative phase in addition to controlling input impedance and distribution of rf power. Thus, control of relative phase, MOTMN input impedance and distribution of rf power at outputs of the MOTMN may be accomplished by having one or more tunable elements (and/or tuning of element value(s)) whose selected values enable control of relative phase in addition to controlling input impedance and distribution of rf power.

The MOTMN includes a number of tunable element(s) which allow desired control of relative phase of rf signals propagating therethrough, as well as control of MOTMN input impedance and power distribution at outputs of the MOTMN. The particular number of tunable impedance elements to use in any particular application, will depend upon the requirements of the application. After reading the disclosure provided herein, one of ordinary skill in the art will understand how to selected the number and type of tunable impedance elements.

In embodiments, an MOTMN may include means to achieve extremely fast (e.g., on an rf-cycle time scale) and precise tunability. Such high tuning speed (e.g., tuning speed which occurs on an rf-cycle time scale for the particular application) may be achieved by using mechanisms/techniques which allow quick adjustments (such as using frequency, for example,) or by changes in element values (i.e., changes in impedance values of a tunable impedance element) that can be made on a short time scale (i.e., an rf-cycle time scale), such as through phase-switched impedance modulation (PSIM). High precision may be achieved by using tuning mechanisms/techniques that can be made with high resolution, including frequency modulation and phase-switched impedance modulation or other switched-mode techniques of adjusting elements on an rf-cycle time scale.

In embodiments, one or more of the one or more tunable elements may have impedance values which are selectable by frequency control. That is, the tunable elements may have impedance values (element values) selected and/or tuned in response to a frequency of a control signal provided thereto.

An MOTMN provided in accordance with the concepts described herein finds use in a wide variety of applications, including but not limited to: plasma systems; wireless power transfer systems; induction heating systems; rf transmitters including radio frequency (rf) communication systems and radar systems; and power converters including dc-dc, ac-dc, dc-ac and ac-ac converters.

For example, some plasma systems have both a main and an rf bias coil. A multiple-output TMN provided in accordance with the concepts described here could enable both coils to be driven from a single rf amplifier, with power control to the two coils controlled by the MOTMN.

As another example, in a plasma system with multiple coils, a multiple-output TMN provided in accordance with the concepts described here could enable control of plasma uniformity across a wide area with a single rf amplifier.

Wireless power transfer systems and induction heating systems may also have multiple coils, enabling control of power transfer to different loads and/or different spatial locations.

As yet another example, rf communication systems often have different antennas for delivering power to different sectors. In each of these cases, a fast, wide-range multiple-output TMN would allow power control to the different outputs to be achieved with a single rf amplifier or inverter.

As yet another example, a multi-output dc-dc converter could likewise be implemented with a single rf inverter, a multi-output TMN providing multiple ac outputs, and multiple rectifiers to rectify those outputs, with the multi-output TMN used to control the flow of power to (and regulate) the different dc outputs.

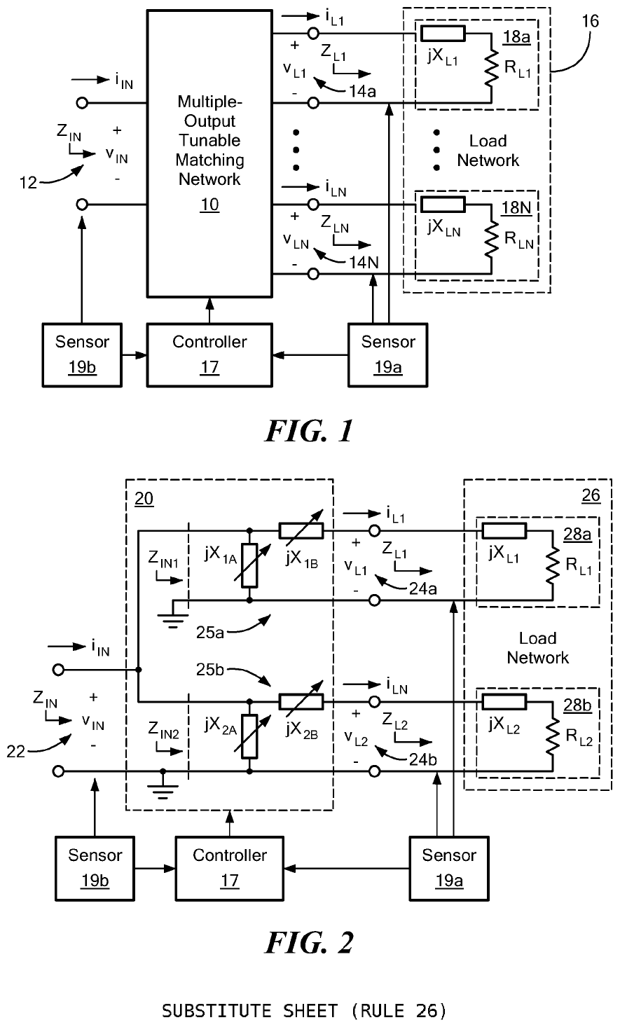

Referring now to FIG. 1, a multiple output tunable matching network (MOTMN) 10 includes an input port 12 and multiple output ports 14a-14N (here N output ports where N is an integer greater than 1). MOTMN presents an input impedance Z_{IN} at MOTMN input port. A load is coupled to at least some of the MOTMN output ports. In the example embodiment of FIG. 1, the load is illustrated as a load network 16 comprising N individual loads 18a-18N with each load having a respective one of independent impedances Z_{L1} to Z_{LN}. The individual loads may thus have independently varying load impedances. It should, however, be appreciated that in embodiments, the loads may have some degree of coupling (e.g., mutual impedance) among them. It should also be appreciated that in embodiments, the load network may comprise a combination of one or more loads with independently varying load impedances and one or more loads with some degree of coupling (e.g., mutual impedance) among them.

As noted above, in the example embodiment of FIG. 1, the loads are illustrated as having independent impedances Z_{L1} to Z_{LN} with each impedance comprising a respective reactive portion (e.g., jX_{L1}-jX_{LN}) and a respective real portion (e.g., R_{L1}-R_{LN}).

The MOTMN 10 can control the relative distribution of power flow from the single input port 12 to each of the output ports 14a-14N, while providing matching of the input impedance to a desired value as the impedances Z_{L1} to Z_{LN} of loads 18a-18N vary.

It is recognized the load network may not actually comprise independent impedances (e.g., may have mutual couplings between some or all of individual loads in the load network), but the techniques described herein can nonetheless be applied to control power flow as described for that case as well.

MOTMN has coupled thereto a controller 17 which provides control signals to MOTMN to control one or more of: (1) an impedance (Z_{IN}) seen at the input of the MOTMN; (2) a distribution of rf power to the multiple outputs of the MOTMN; and (3) phases (including relative phases) of rf signals propagating through the MOTMN.

A sensor 19a senses the individual outputs (e.g., rf voltage and/or current) at each output 14a-14N. Sensor 19 may be provided, for example, as a voltage and current probe (V/I probe) but any type of sensor suitable for measure or otherwise determining voltage and current levels including, but not limited to impedance sensors, may be used. Sensor 19 provides the sensed or determined signals (or information) to controller 17. In some embodiments a V/I sensor may sense rf voltage and current and hence can sense the input impedance.

Controller 17 sends signals to the MOTMN that adjusts element values (e.g., reactive element values) within the MOTMN. Controller 17 may optionally include a frequency command output that may be provided to an element (e.g., an rf source and/or an rf amplifier such as an rf power amplifier) supplying an rf signal the MOTMN. Techniques for steering power and controlling input impedance are described below for example implementations.

A sensor 19b senses one or more signals (e.g., rf voltage and/or current signals) at the MOTMN input 12. Sensor 19b may be provided, for example, as a voltage and current probe (V/I probe) but any type of sensor suitable for measure or otherwise determining voltage and current levels including, but not limited to impedance sensors, may be used. Sensor 19b provides the sensed or determined signals (or information) to controller 17. In some embodiments a V/I sensor may sense rf voltage and current and hence can sense the input impedance.

Thus, sensors 19a, 19b respectively provide feedback from measurements of the load impedances (via sensor 19a at the outputs of MOTMN) and a measurement of the input impedance (via sensor 19b at the input of MOTMN).

Given a load impedance on one of the MO TMN branch outputs (e.g., ZL1), standard matching network equations as are well-known in the art given the required setpoints of the reactance elements to get a specified input resistance for that branch. In embodiments the values of the variable elements can be selected via a control loop (e.g., the loop provided by sensors 19as, 19b an controller 17) provided to drive the input resistance of each branch leading to outputs 14a-14N towards a desired value and drive the reactance of the branch towards zero or some other desired value (i.e. values of the reactance elements may be determined without use of the measurements and equations). By dynamically adjusting the targeted sum of the inverses of Z_{IN1} and Z_{IN2} the input impedance Z_{IN} can be controlled and by adjusting the relative values of R_{IN1} and R_{IN2}, the power distribution between the two outputs to a desired value can be adjusted.

Referring now to FIG. 2, an example embodiment of a TMN 20 having a single input 22 and two-outputs 24a, 24b includes a pair of interconnected single-input, single-output L-section matching networks 25a, 25b (also sometimes referred to herein as “MOTMN branches” 25a, 25b or more “simply branches” 25a, 25b).

In this example embodiment, L-section matching network 25a comprises two tunable reactive components (also sometimes referred to herein as “reactive elements,” “tunable impedance elements” or more simply “tunable elements”) having impedance characteristics jX_{1A}, jX_{1B}, arranged in an “L-section” network. Two tunable elements are generally necessary to transform a load impedance Z_{L}=R_{L}+jX_{L} having a variable resistance R_{L} and reactance X_{L} to a resistive input impedance Z_{IN}=R_{IN}. This can be accomplished with a small number of tunable reactive components (here two tunable reactive components per branch using the “L-section” network as illustrated in FIG. 2. The tunable elements may be provided as one or more tunable (or variable) inductive elements (e.g., variable inductors), one or more tunable (or variable) capacitive elements (e.g., variable capacitors), or one or more tunable (or variable) resistive elements (e.g., variable resistors). In embodiments, the tunable elements may be provided as any combination of variable inductive, capacitive or resistive elements,

In the example embodiment of FIG. 2, L-section matching network 25b comprises two tunable reactive components (or tunable elements) arranged in an “L-section” network. The L-section network 25a is capable of transforming a load impedance Z_{L}=R_{L}+jX_{L} to have an input resistance component Re{Z_{IN1}}>R_{L1}, while the L-section network 25b can transform a load impedance Z_{L2} to an have an input component Re{Z_{IN2}}>R_{L2}.

Thus, the pair of interconnected single-input, single-output L-section matching networks 25a, 25b together comprise four variable reactance elements designated in FIG. 2 as jX_{1A}, jX_{1B}, jX_{2A} and jX_{2B}. Variable reactance elements jX_{1A}, jX_{1B}, jX_{2A} are input-side shunt elements responsive to one of PSIM or DFT tuning techniques.

In embodiments, the variable reactance elements may be provided as any circuit element having a variable capacitance (e.g., one or more variable capacitors) and/or any circuit element having a variable inductance (e.g., a variable inductor). Variable capacitance elements can be realized using a variety of methods known in the art, including variable vacuum capacitors (e.g., driven from a servo), switched capacitor banks, capacitive phase-switched impedance modulation networks, and resonant tanks driven at variable frequency. Variable inductor elements can be realized using LC networks having variable capacitors, by mechanically-variable inductor components, by inductive phase-switched impedance modulation networks, and by resonant tanks driven at variable frequency.

By controlling tunable reactance values jX_{1A}, jX_{1B}, jX_{2A} and jX_{2B}, of one or more of the plurality of the tunable reactance elements, one can obtain real-valued branch input impedances Z_{IN1}=R_{IN1}=1/Y_{IN1}=1/G_{IN1} and Z_{IN2}=R_{IN2}=1/Y_{IN1}=1/G_{IN2} that are larger than resistance values R_{L1} and R_{L2}, respectively. R_{IN1} and R_{IN2} determine the power that flows to Z_{L1} and Z_{L2} for a given voltage V_{IN}, so being able to control their values enables control of relative and absolute power flowing to each load.

One may also obtain a net input impedance Z_{IN}=R_{IN}=1/(Y_{IN1}+Y_{IN2})=1/(G_{IN1}+G_{IN2}). By controlling R_{IN1} and R_{IN2} (and consequently G_{IN1}+G_{IN2}) it is possible to control the net input impedance Z_{IN} as desired for the MOTMN.

The tunable reactance elements may be controlled, for example, via controller 17 which provides control signals to one or more of the tunable reactance elements. Controller 17 and sensors 19a, 19b may be the same as or similar to the controller and sensors described above in conjunction with FIGS. 1 and 2. Such control signals may take the form of analog or digital current and/or voltage signals. The net input impedance may thus be controlled by controlling the sum of the input conductances.

As noted above, controller 17 may receive feedback from measurements of the load impedances (e.g., via sensor 19a) and a measurement of the input impedance from sensor 19b. Given a load impedance on one of the branches (e.g., Z_{L1}), known matching network equations may be used to compute or otherwise determine required setpoints of the reactance elements to obtain a specified input resistance for that branch (R_{IN1} or more generally Z_{IN1}). Additionally or alternatively (e.g., without use of the measurements and equations), the values of the two variable elements may be arrived at with a control loop (e.g. formed by controller 17 and sensors 19a, 19b) to drive the input resistance of each branch towards a desired value (e.g., R_{IN1}) and drive the reactance of the branch towards zero or some other desired value (e.g., X_{IN1}). By dynamically adjusting the targeted sum of the inverses of Z_{IN1} and Z_{IN2} the input impedance Z_{IN} can be controlled and by adjusting the relative values of R_{IN1} and R_{IN2} the power distribution between the two outputs can be adjusted to desired values

At the same time, the fraction of total rf power P_{TOT} flowing from the input port 22 to outputs ports 24a, 24b (with respective power levels P₁ and P₂) may be controlled through the relative proportion of the input conductances:

$$\frac{{P}_{1}}{{P}_{TOT}} = \frac{{G}_{1}}{{G}_{1} + {G}_{2}} \frac{{P}_{2}}{{P}_{TOT}} = \frac{{G}_{2}}{{G}_{1} + {G}_{2}} , \qquad ( 1 )$$

In which:
P₁ is the power level at a first output port of a two-output port TMN;
P₂ is the power level at a second output port of a two-output port TMN;
P_{TOT} is the total amount of power flowing from an input port to the output ports of a single input, two-output port TMN; is the shunt conductance;
G₁ is the shunt conductance at a first branch of a single input, two-output port TMN; and
G₂ is the shunt conductance at a second branch of a single input, two-output port TMN.

Two-output TMN 20 thus achieves the desired goals for two outputs with four tunable reactance elements.

While the system of FIG. 2 described above provided the desired functions (e.g., controlling the relative distribution of power flow from a single input port to each of multiple output ports while providing matching of an input impedance to a desired value as load impedances vary), it is possible to use fewer tunable elements to do so, which can benefit the size, cost and performance of a multi-output TMN system.

In embodiments, tunable reactance elements may be realized as variable (tunable) components, i.e., their impedance at a particular frequency, or over a range of frequencies, can be controlled externally. The particular topology of the MOTMNs that one may choose to employ and the decision as to which reactive elements in the matching network to realize as variable components depends upon application requirements, and may also depend on the specific techniques employed for implementing the variable components. Example topologies in accordance with the concepts described herein are described herein.

The variable reactance elements in an MOTMN may be provided as continuously adjustable (“analog”) or discretely adjustable (“digital”) among a limited set of values. Continuously variable reactance elements include those whose value (at some frequency or over a range of frequencies) can be tuned in a continuous manner (or effectively continuous for practical purposes), such as by appropriately adjusting bias conditions of varactors or through the use of mechanically-adjustable variable capacitors (such as variable-vacuum capacitors) driven with servo motors. Other techniques for realizing continuously-adjustable reactance values include dynamic frequency tuning (DFT) and phase-switched impedance modulation (PSIM).

Discretely adjustable variable reactance elements (also referred to as “digital variable reactance elements”) may be realized as digitally-switched arrays of reactance components that allow adjustment of the impedance of the variable reactances in finite and discrete steps. The realization of digital TMN may be based upon complementary metal oxide semiconductor (CMOS) switches, micro-electromechanical system (MEMS) switches, PIN diodes or discrete power transistors. Thus, MOTMNs described herein may comprise a combination of discretely-tuned elements and continuously-tunable elements.

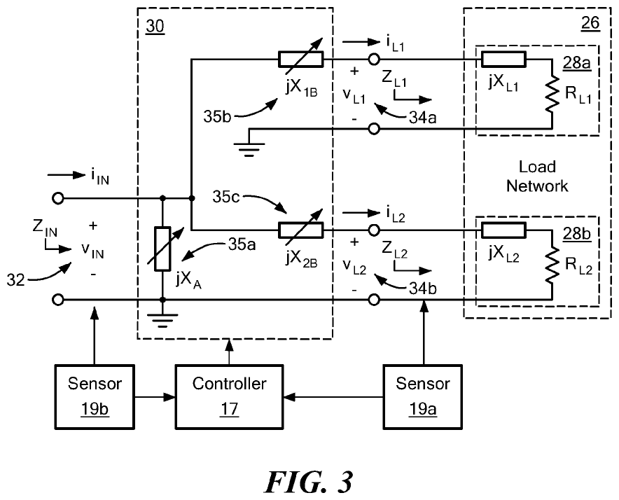

Referring now to FIG. 3 a multiple output TMN accomplishes substantially the same functionality as TMN 20 (FIG. 2) but with only three tunable reactance elements 35a, 35b, 35c (as opposed to the four variable reactive element used in the example embodiment of FIG. 2). Tunable reactance element 35a is input-side shunt element responsive to one of PSIM or DFT tuning techniques. Tunable reactance elements 35a, 35b, 35c have respective tunable impedance values jX_{A}, jX_{1B}, and jX_{2B}. In this system, the reactance value jX_{A} is controlled (e.g., via a controller as equal to the reactance value of element jX_{1A} (FIG. 2) taken in parallel with reactance value of element jX_{2A} (FIG. 2) (i.e., jX_{1A}J∥jX_{2A} used in the system of FIG. 2).

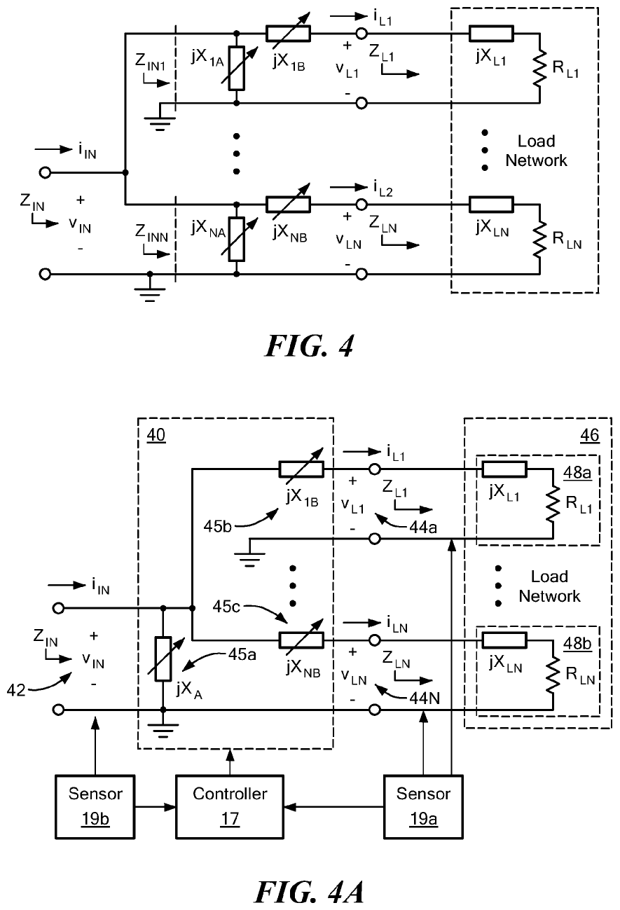

The approach illustrated in FIGS. 2 and 3 are directly extensible to N outputs, as illustrated in FIGS. 4 and 4A.

FIG. 4 illustrates a so-called “non-reduced” version of the MOTMN of FIG. 2 which has two elements for each branch (i.e., FIG. 4 expands the circuit of FIG. 2 from two branches to N branches). FIG. 4A illustrates a “reduced” version of the MOTMN (i.e., a version of the MOTMN having fewer (and ideally a minimum number of) reactive elements. Variable reactance elements 45a is an input-side shunt elements responsive to one of PSIM or DFT tuning techniques.

The example network of FIG. 4 illustrates N connected single-output L-section matching networks which are tunable to provide individual input admittances Y_{IN1} to Y_{INN} (=1/Z_{IN1} to 1/Z_{INN}), and yielding a net input admittance Y_{IN}=Y_{IN1}+ . . . +Y_{INN}. By tuning jX_{jA}=1/Y_{jA} and jX_{jB}=1/Y_{jB} to make 1/Z_{INj}=Y_{INj} to be a conductance Gⱼ, one can control the net input conductance (and hence resistance) and control the fraction of power to the jth output as:

$$\frac{{P}_{j}}{{P}_{TOT}} = \frac{{G}_{j}}{{G}_{1} + … + {G}_{N}} \qquad ( 2 )$$

Where the net input resistance R_{IN} is

$${R}_{IN} = \frac{1}{{G}_{1} + … + {G}_{N}} \qquad ( 3 )$$

The multi-output tunable matching network of FIG. 4A thus achieves the same function as the embodiment of FIG. 4, but does so using a minimum N+1 controllable reactance elements. It is controlled as in the manner of the TMN of FIG. 4 with jX_{A}=1/(Y_{1A}+ . . . +Y_{NA}).

Since the circuits and techniques described herein control the equivalent input conductances G_{INj} to values below that of their respective load conductances G_{Lj}, it is recognized that the ability to control the net input impedance and relative power flows in the above step-up matching networks does depend upon the range of load impedances at the individual outputs.

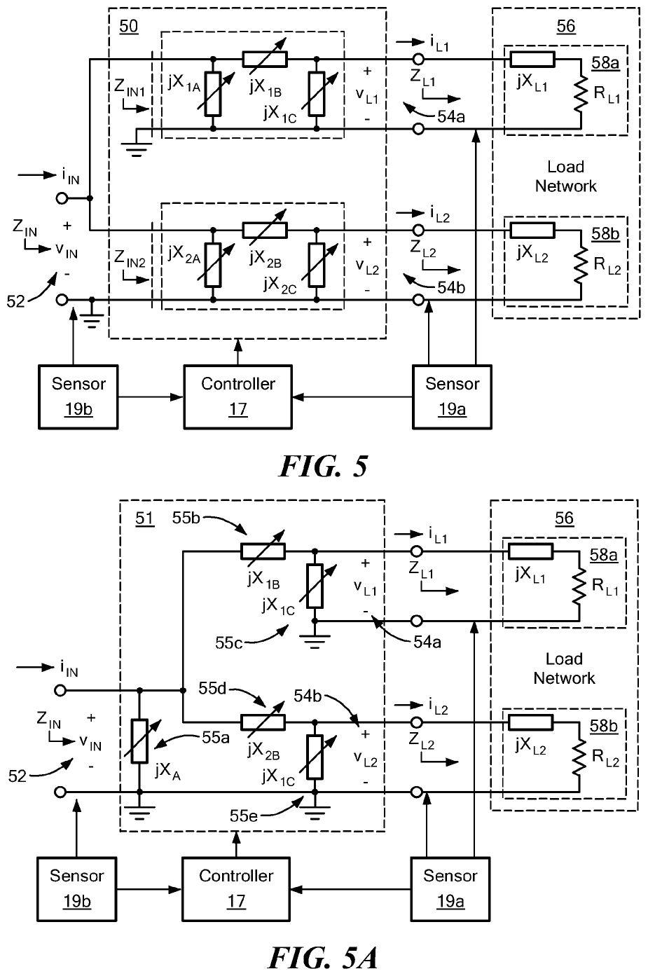

This may be addressed using the multiple-output matching networks based on “extended pi” multi-output tunable matching networks. Two-output implementations of this approach are shown in FIGS. 5 and 5A.

Referring now to FIG. 5, a single input two-output tunable matching network comprises two inter-connected pi matching networks (having six tunable elements) to support two outputs.

With sufficient tuning ranges, the T- and Pi-section networks of FIGS. 5 and 5A can transform a load impedance Z_{L} to an input impedance Z_{IN}, which may be selected to have a real part R_{IN} which may be larger or smaller than load resistance R_{L}. (with ZIN optionally selectable to be purely real, i.e., Z_{IN}=R_{IN}). Moreover, unlike L-section networks, T- and Pi-section networks have the characteristic that they are capable of controlling relative phases of input and output voltages v_{IN} and v_{L} across load and/or input impedance levels. Of course, still higher-numbers of tunable elements can be used, and a tunable network may be augmented with fixed elements or matching stages.

As the pi networks support creating input resistances above or below that of their respective load resistances, the restriction on matching and power flow control of the networks of FIGS. 2 and 3 are eliminated.

Referring now to FIG. 5A, by combining variable reactance elements jX_{1A} and jX_{2A} (from the two-output tunable matching network of FIG. 5) as a single variable reactance element 55a having a reactance value jX_{A} controlled to jX_{A}=X_{1A}∥X_{2A}, one may obtain a tunable matching network having the same capabilities, using fewer elements than required in the implementation of FIG. 5. As shown in FIG. 5A, MOTMN 51 includes a minimum of five (5) tunable elements with variable reactance element 55a corresponding to an input-side shunt element responsive to one of PSIM or DFT tuning techniques.

It should be noted that in addition to providing greater flexibility in power transfer, the multi-output TMNs of FIGS. 5 and 5A provide sufficient freedom to regulate the relative phases of the voltages V_{L1} and V_{L2} with respect to the input voltage V_{IN}. This may be accomplished by dynamically adjusting the “center resistance” of each of the pi networks in FIG. 5. The ability to control relative phase between input and output for a pi matching network is known for fixed single-output matching networks, e.g., as described in W. L. Everitt and G. E. Anner, Communication Engineering, 3rd ed., New York: McGraw-Hill, 1956, ch. 11.

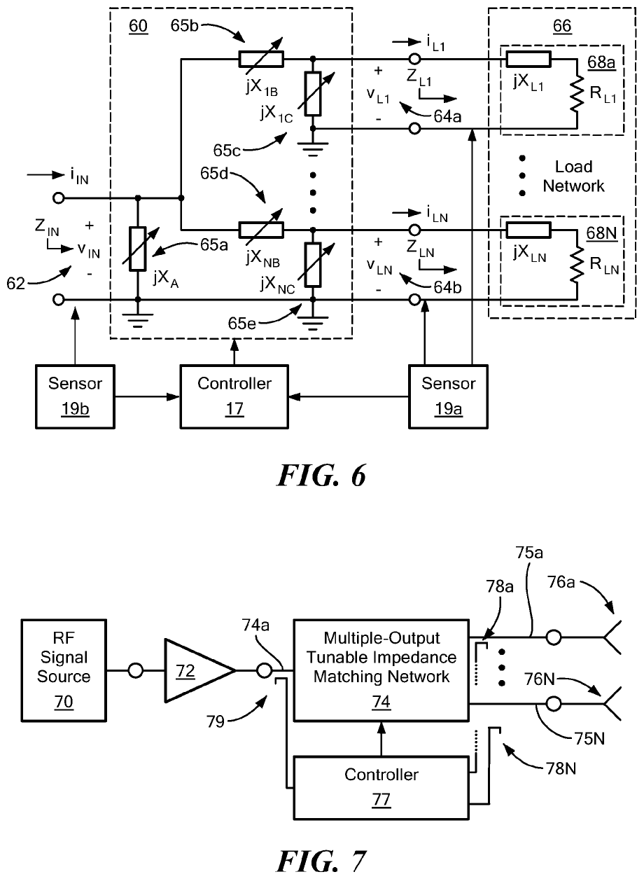

Just as the designs illustrated in FIGS. 2 and 3 extend to N outputs (FIG. 4), the design of FIG. 5A can be extended to an N-output system using a minimum of 2N+1 tunable elements as shown in FIG. 6.

Referring now to FIG. 6, It should be noted the embodiment of FIG. 6 includes fewer than the 3N elements required for a direct extension of the two-output system of FIG. 5. As with the 2-output systems of FIGS. 5, 5A, the multiple output tunable matching network provides both wide flexibility in power control, and the ability to adjust relative phases of each output voltage with respect to the input voltage.

It should, of course, be appreciated that designs intermediate between those of FIGS. 4 and 6 exist having different limitations on relative ranges of allowed load impedance and on which phases may be adjusted with respect to which, and correspondingly having intermediate numbers of tunable components.

It will be appreciated that one may want to intentionally select different mechanisms for the different tunable elements in a multi-output TMN. For example, very fast tuning might be desirable for the input-side shunt element 35a, 45a, 65a in FIG. 3, 4, or 6 respectively, such that one might chose PSIM or frequency modulation (also known as dynamic frequency tuning or DFT) for tuning this element. Likewise, one may be able to use discretely-tuned elements (e.g., digitally controlled circuit elements) for a subset of the elements (e.g., N elements an N-output system) and continuously-tunable elements (e.g., analog controlled circuit elements) for the others while still achieving acceptable relative phase among outputs and acceptable precision of net impedance and relative power control.

Referring now to FIG. 7, a system employing a multiple output tunable matching network (MOTMN) 74 includes an rf signal source to which provides an rf signal to an input of an rf amplifier 72. RF amplifier 72 may, for example, be an rf power amplifier (PA). An output of rf amplifier 72 is coupled to an input of multiple output tunable matching network 74. Multiple output tunable matching network 74 may be, for example, any of the types of multiple output tunable matching networks described above in conjunction with FIGS. 1-6.

Each output 75a-75N of multiple output tunable matching network 74 may be coupled a respective ones of a plurality of loads 76a-76N.

The system includes a controller 77 which provides control signals to MOTMN 74 to control one or more of: (1) an impedance (Z_{IN}) seen at the input of the MOTMN; (2) a distribution of rf power to the multiple outputs of the MOTMN; and (3) phases (including relative phases) of rf signals propagating through the MOTMN.

A sensor 78 (which may comprise a plurality of individual sensors 78a-78N) coupled to respective ones of outputs 75a-75N senses the individual outputs (e.g., rf voltage and/or current) at each MOTMN output 75a-75N. Sensor 78 may comprise, for example, one or more voltage and current probes (V/I probes) and/or one or more rf coupler circuits. It is noted, however, that any type of sensor suitable for measuring, detecting or otherwise determining voltage and current levels (including, but not limited to impedance sensors), may be used. In some embodiments a V/I sensor may sense rf voltage and current and hence can sense the input impedance. Sensor 78 provides the sensed or determined signals (or information) to controller 77.

Controller 77 sends signals to the MOTMN 74 that adjusts impedance values (e.g., reactive values) of tunable reactance elements within the MOTMN. Controller 77 may optionally include a frequency command output that may be provided to one or more elements (e.g., an rf source and/or an rf amplifier such as an rf power amplifier) supplying an rf signal the MOTMN.

Sensor 78 may comprise, for example, one or more voltage and current probes (V/I probes) and/or one or more rf coupler circuits. It is noted, however, that any type of sensor suitable for measuring, detecting or otherwise determining voltage and current levels (including, but not limited to impedance sensors), may be used. In some embodiments a V/I sensor may sense rf voltage and current and hence can sense the input impedance. Sensor 78 provides the sensed or determined signals (or information) to controller 77.

A sensor 79 senses one or more signals (e.g., rf voltage and/or current signals) at the MOTMN input 74a. Sensor 78 may comprise, for example, a voltage and current probe (V/I probe) and/or one or more rf coupler circuits. Any type of sensor suitable for measure or otherwise determining voltage and current levels including, but not limited to impedance sensors, may also be used. Sensor 79 provides the sensed or determined signals (or information) to controller 77.

Thus, sensors 78, 79 respectively provide feedback from measurements of the load impedances (via sensor 78 at the outputs of MOTMN) and a measurement of the input impedance (via sensor 79) at the input of MOTMN).

In embodiments, the system of FIG. 7 may represent a plasma system (or a portion of a plasma system) such as a portion high power microwave plasma system used in connection with wafer processing systems (e.g., for chamber cleaning or for on-wafer processes). In this case, loads 76a-76N may be coils of the plasma systems (e.g., a main and an rf bias coil). In this case, multiple-output TMN 74 enables multiple coils to be driven from a single rf amplifier 72, with power control to the coils controlled by the multiple-output TMN 74 in the manner described hereinabove.

As another example, the system of FIG. 7 may correspond to a portion of a plasma system with multiple coils and the multiple-output TMN 74 enables control of plasma uniformity across a wide area with single rf amplifier 72. Impedance of the coils can vary significantly with frequency as well as with operating conditions that can result in great impedance variations caused by various factors such as changing characteristics of the plasma. The use of a MOTMN as described herein is suitable for realizing accurate matching over a wide frequency range. To realize desired (and ideally, optimum) performance in terms of power and efficiency, it is therefore necessary to utilize an automatically tunable MOTMN that can dynamically control (1) an impedance (Z_{IN}) seen at the input of the MOTMN; and/or (2) a distribution of rf power to the multiple outputs of the MOTMN; and/or (3) phases (including relative phases) of rf signals propagating through the MOTMN. In this example embodiment, the coils correspond to a plurality of loads which may collectively correspond to a load network and the loads (i.e., the coils) which have independent impedances and where mutual couplings exists among at least some of the plurality of loads. In some high-power applications where accurate impedance matching is required over a very wide impedance range (e.g., for rf plasma drive), the MOTMN 74 may comprise a combination of discretely-tuned elements and continuously-tunable elements. In embodiments, discretely-tuned elements are selected for a first subset of the elements and continuously-tunable elements are selected for the second subset of the elements while still achieving acceptable relative phase among outputs and acceptable precision of net impedance and relative power control. In embodiments, the MOTMN 74 may comprise tunable reactance elements provided as upon one or more of: stepper motor-adjusted variable capacitors, dynamic frequency tuning, and phase-switched impedance modulation. Such components allow the MOTMN to meet requirements for accurate impedance matching and operation over very wide impedance ranges.

Alternatively, the system of FIG. 7 may correspond to a wireless power transfer system or an induction heating system having multiple coils 76a-76N, enabling control of power transfer to different loads and/or different spatial locations.

Alternatively, the system of FIG. 7 may correspond to a portion of an rf communication systems having different antennas 76a-76N for delivering power to different sectors in a field of view.

In each of the above use-case examples, a fast, wide-range multiple-output TMN would allow power control to the different outputs to be achieved with a single rf amplifier or inverter.

Alternatively still, the system of FIG. 7 may correspond to a portion of a multi-output dc-dc converter implemented with a single rf inverter, a multi-output TMN providing multiple ac outputs, and multiple rectifiers to rectify those outputs, with the multi-output TMN used to control the flow of power to (and regulate) the different dc outputs.

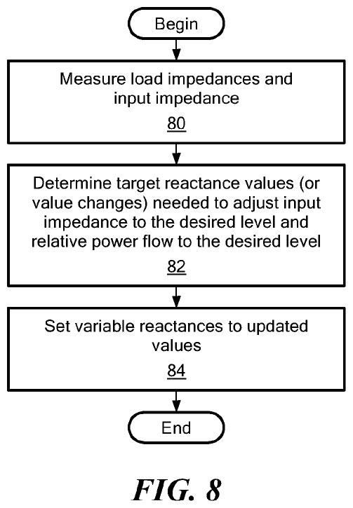

Referring now to FIG. 8, a method for operating an MOTMN begins by measuring or otherwise determining one or more load impedances and/or input impedance of the MOTMN. The measured or otherwise determined values (e.g., voltage, current or impedance values of the load(s) and/or voltage, current or impedance values of the input) are used to calculate or otherwise determine target reactance values (or changes in values) of one or more tunable reactive elements. The target reactance values are those needed to adjust input impedance to desired levels and/or to adjust relative power flow to desired levels.

In some embodiments, it might be desirable to adjust set points on the variable reactance elements that are in “steps” that don't exactly correspond to the reactance values taken on by the one or more tunable reactive elements.

In processing block 84, the reactance values of one or more tunable reactive elements are set or updated to the determined values.

Although reference is made herein to particular circuits, components, elements and designs, it is appreciated that other circuits components, elements and designs having similar functional and/or structural properties may be substituted where appropriate, and that a person having ordinary skill in the art would understand how to select such materials and incorporate them into embodiments of the concepts, techniques, and structures set forth herein without deviating from the scope of those teachings.

Various embodiments of the concepts, systems, devices, structures and techniques sought to be protected are described herein with reference to the related drawings. Alternative embodiments can be devised without departing from the scope of the concepts, systems, devices, structures and techniques described herein.

It is noted that various connections and positional relationships (e.g., elements which are directly coupled and elements which are indirectly coupled, etc.) are set forth between elements in the following description and in the drawings. These connections and/or positional relationships, unless specified otherwise, can be direct or indirect, and the described concepts, systems, devices, structures and techniques are not intended to be limiting in this respect. Accordingly, a coupling of entities (or elements or components) can refer to either a direct or an indirect coupling, and a positional relationship between entities can be a direct or indirect positional relationship. The term “connection” can include an indirect “connection” and a direct “connection” between two or more elements. The term “direct connection” means that a first element, such as a first structure, and a second element, such as a second structure, are connected without any intermediary elements.

As an example of an indirect positional relationship, references in the present description to coupling element “A” to element “B” include situations in which one or more intermediate elements (e.g., element “C”) is between element “A” and element “B” as long as the relevant characteristics and functionalities of the coupled elements are not substantially changed by the intermediate element.

The following definitions and abbreviations are to be used for the interpretation of the claims and the specification. As used herein, the terms “comprises,” “comprising, “includes,” “including,” “has,” “having,” “contains” or “containing,” or any other variation thereof, are intended to cover a non-exclusive inclusion. For example, a circuit, network, method, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance, or illustration. Any embodiment or design described herein as “exemplary” is not necessarily to be construed as preferred or advantageous over other embodiments or designs.

The terms “one or more” and “one or more” are understood to include any integer number greater than or equal to one, i.e., one, two, three, four, etc. The term “a plurality” is understood to include any integer number equal to or greater than two, i.e. two, three, four, five, etc.

References in the specification to “one embodiment, “an embodiment,” “an example embodiment,” etc., indicate that the embodiment described can include a particular feature, structure, or characteristic, but every embodiment can include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value.

The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

It is to be understood that the disclosed subject matter is not limited in its application to the details of construction and to the arrangements of the components set forth in the following description or illustrated in the drawings. The disclosed subject matter is capable of other embodiments and of being practiced and carried out in various ways. Also, it is to be understood that the phraseology and terminology employed herein are for the purpose of description and should not be regarded as limiting. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

1. A multi-output tunable matching network (MOTMN) having an input port and a plurality of output ports with each output port configured to have one or more loads coupled thereto and wherein at least one of the loads has an impedance which varies, the MOTMN comprising:
a like plurality of branches with each branch having a first end coupled to the input of the MOTMN and a second end coupled to a respective ones of the plurality of MOTMN outputs; and
each branch of the plurality of branches comprising one or more tunable reactive elements, wherein the tunable reactive elements are provided having reactance values selected to: (1) control the distribution of power flow from the MOTMN input to ones of the plurality of outputs of the MOTMN as load impedances vary; and (2) match an input impedance at the single input of the MOTMN to a desired value even as load impedances vary.

2. The multi-output tunable matching network of claim 1 comprising N+1 tunable reactive elements where N is an integer corresponding to the number of outputs in the multi-output tunable matching network.

3. The multi-output tunable matching network of claim 1 comprising 2N tunable reactive elements where N is an integer corresponding to the number of outputs in the multi-output tunable matching network.

4. The multi-output tunable matching network of claim 1 wherein at least one of the tunable reactive elements is a discretely-tuned element and at least one of the tunable reactive elements is continuously-tunable element.

5. The multi-output tunable matching network of claim 1 wherein at least one of the tunable reactive elements is a discretely-tuned elements are selected for a first subset of the elements and continuously-tunable elements are selected for the second subset of the elements while still achieving acceptable relative phase among outputs and acceptable precision of net impedance and relative power control.

6. A multi-output tunable matching network (MOTMN) comprising:
at least one input;
a plurality of outputs, each output configured to be coupled to a load network;
a plurality of tunable reactive elements having variable reactance values, each of the tunable reactive elements coupled between the at least one input and at least one of the plurality of outputs;
a controller for controlling the variable reactance values of one or more of the tunable reactive elements to achieve (1) relative distribution of power flow from the at least one input to ones of the plurality of MOTMN outputs; and (2) substantially match the input impedance of the MOTMN to a desired value even as impedances presented to one or more of the plurality of outputs of the TMN by the load network vary.

7. The multi-output tunable matching network of claim 6 comprising 2N+1 tunable reactive elements where N is an integer corresponding to the number of outputs in the multi-output tunable matching network.

8. The multi-output tunable matching network of claim 6 comprising 3N tunable reactive elements where N is an integer corresponding to the number of outputs in the multi-output tunable matching network.

9-15. (canceled)

16. An extended pi multi-output tunable matching network comprising:
a first plurality of interconnected pi matching networks having a second plurality of variable reactance elements to support a third plurality of outputs wherein the pi networks support creating input resistances above or below that of their respective load resistances and wherein a single reactance is controlled to jX_{A}=X_{1A}∥X_{2A}.

17. The extended pi multi-output tunable matching network of claim 16 comprising 2N+1 variable reactance elements for N outputs of the extended pi multi-output tunable matching network.

18. The extended pi multi-output tunable matching network of claim 16 comprising 3N variable reactance elements for N outputs of the extended pi multi-output tunable matching network.

19. The extended pi multi-output tunable matching network of claim 16 comprising:
means for dynamically adjusting a center resistance of each of the pi networks to regulate relative phases of voltages v_{L1} and v_{L2} with respect to an input voltage v_{IN}.

20. The extended pi multi-output tunable matching network of claim 16 wherein:
the plurality of interconnected pi matching networks is provided as two interconnected pi matching networks having six tunable variable reactance elements to support two outputs.

21. The extended pi multi-output tunable matching network of claim 16 wherein:
the plurality of interconnected pi matching networks is provided as two interconnected pi matching networks having five variable reactance elements to support two outputs.

22. The extended pi multi-output tunable matching network of claim 16 wherein the pi networks support creating input resistances above or below that of their respective load resistances.

23-25. (canceled)

26. The multi-output tunable matching network (MOTMN) of claim 6 wherein the MOTMN has a pair of outputs and the plurality of tunable reactive elements comprise:
a pair of interconnected single-input, single-output L-section matching networks coupled to respective ones of the pair of MOTMN outputs, the interconnected single-input, single-output L-section matching networks having four variable reactance elements having respective ones of variable reactance values X_{1A}, X_{1B}, X_{2A} and X_{2B}; and
a controller coupled to the pair of interconnected single-input, single-output L-section matching networks, wherein in response to inputs provided to the controller, the controller provides control signals to set reactance values X_{1A}, X_{1B}, X_{2A} and X_{2B} of the variable reactance elements to obtain real-valued branch input impedances Z_{IN1}=R_{IN1}=1/Y_{IN1}=1/G_{IN1} and Z_{IN2}=R_{IN2}=1/Y_{IN1}=1/G_{IN2} that are larger than load impedances R_{L1} and R_{L2}.

27. The multi-output tunable matching network (MOTMN) of claim 26 wherein the reactance values X_{1A}, X_{1B}, X_{2A} and X_{2B} of the variable reactance elements are set to provide a net input impedance Z_{IN}=R_{IN}=1/(Y_{IN1}+Y_{IN2})=1/(G_{IN1}+G_{IN2}).

28. The multi-output tunable matching network (MOTMN) of claim 27 wherein the reactance values X_{1A}, X_{1B}, X_{2A} and X_{2B} of the variable reactance elements are set such that a sum of the input conductances control a net input impedance of the TMN.

29. The multi-output tunable matching network of claim 7 wherein N=2 and the multi-output tunable matching network comprises five (5) tunable reactance elements having ones of tunable impedances jX_{A}, jX_{1B}, and jX_{2B}; and
the controller controls the values of the five tunable reactance elements such a desired proportion of power from the input is delivered to each output and the input impedance of the multi-output tunable matching network is controlled to a desired value.

30. The multi-output tunable matching network (MOTMN) of claim 6 wherein the MOTMN has a pair of outputs and the plurality of tunable reactive elements comprises:
N connected single-output L-section matching networks where N is an integer greater than one and N connected single-output L-section matching networks are tunable to provide individual input admittances Y_{IN1} to Y_{INN} (=1/Z_{IN1} to 1/Z_{INN}), and yielding a net input admittance Y_{IN}=Y_{IN1}+ . . . +Y_{INN}; and
wherein by tuning jX_{Aj}=1/Y_{Aj} and jX_{Bj}=1/Y_{Bj} to make 1/Z_{INj}=Y_{INj} to be a conductance Gⱼ, a net input conductance and the fraction of power to a jth output can be controlled as:
$$\frac{{P}_{j}}{{P}_{TOT}} = \frac{{G}_{j}}{{G}_{1} + … + {G}_{N}}$$
where the net input resistance R_{IN} is
$${R}_{IN} = \frac{1}{{G}_{1} + … + {G}_{N}}$$
